(19) United States
(12) Patent Application Publication
(10) Pub. No.: US 2011/0231139 A1
(43) Pub. Date: Sep. 22, 2011

(54) INFORMATION PROCESSOR

(75) Inventors: Koichi Yokota, Kawasaki (JP); Shinichi Shiotsu, Kawasaki (JP); Isamu Yamada, Kawasaki (JP)

(73) Assignee: FUJITSU LIMITED, Kawasaki-shi (JP)

(21) Appl. No.: 13/049,208

(22) Filed: Mar. 16, 2011

(30) Foreign Application Priority Data
Mar. 19, 2010 (JP) 2010-64165

(51) Int. Cl. G01R 35/00; G06F 19/00

(52) U.S. Cl. 702/104

(57) ABSTRACT

An information processor includes: a contact sensing unit that senses contact; a capacitance sensing unit that senses capacitance; a capacitance offset information storage unit that stores offset capacitance information; a contact state change determining unit that obtains information indicating a contact state from the contact sensing unit and determines a change in the contact state sensed by the contact sensing unit; a capacitance correction control unit that obtains capacitance information from the capacitance sensing unit when the change in the contact state is determined by the contact state change determining unit, and updates offset capacitance information stored in the capacitance offset information storage unit with the obtained capacitance information; and a capacitance correction calculation unit that obtains the capacitance information from the capacitance sensing unit and uses the offset capacitance information stored in the capacitance offset information storage unit to correct the obtained capacitance information.

### CROSS-REFERENCE TO RELATED APPLICATIONS

This application is based upon and claims the benefit of priority of the prior Japanese Patent Application No. 2010-64165, filed on Mar. 19, 2010, the entire contents of which are incorporated herein by reference.

### FIELD

Embodiments of the present invention are related to an information processor that has a capacitance detection device.

### BACKGROUND

There is an information processor, such as a mobile terminal, that uses a capacitance sensor to detect user operations. For example, a mobile terminal that has a touch panel using a capacitance sensor detects user operations when a capacitance sensor senses contact by a user on a touch panel.

A technique is known in which capacitance detecting elements installed in a portable electronic device work in conjunction with contact motions operated by a user with a finger or the like to sense capacitance (hereinafter, a finger or the like is referred to as a finger). Further, a technique is known in which a portable electronic device compares sensed capacitance value to a threshold level to determine a coordinate point touched with a finger by a user. There is also an electronic device that determines positions touched by a user based on coordinate points of capacitance detecting element whose capacitance have changed.

### SUMMARY

According to an aspect of the invention, an information processor includes: a contact sensing unit that senses contact; a capacitance sensing unit that senses capacitance; a capacitance offset information storage unit that stores offset capacitance information; a contact state change determining unit that obtains information indicating a contact state from the contact sensing unit and determines a change in the contact state sensed by the contact sensing unit; a capacitance correction control unit that obtains capacitance information from the capacitance sensing unit when the change in the contact state is determined by the contact state change determining unit, and updates offset capacitance information stored in the capacitance offset information storage unit with the obtained capacitance information; and a capacitance correction calculation unit that obtains the capacitance information from the capacitance sensing unit and uses the offset capacitance information stored in the capacitance offset information storage unit to correct the obtained capacitance information.

The object and advantages of the invention will be realized and attained by at least the features, elements, and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIGS. 1A and 1B illustrate examples of an information processor that has capacitive sensors.

FIGS. 2A to 2C illustrate examples of usage states of an information processor that has high-sensitivity capacitive sensors.

FIGS. 3A to 3C illustrate examples of usage states of an information processor held by a user.

FIG. 4 illustrates an information processor according to an embodiment.

FIG. 5 illustrates an example of a hardware configuration of the information processor according to the embodiment.

FIG. 6 illustrates an example of a functional configuration of a capacitance correction unit according to the embodiment.

FIG. 7 illustrates an example of contact state information stored in a contact state information storage unit according to the embodiment.

FIG. 8 illustrates an example of capacitance offset information stored in a capacitance offset information storage unit according to the embodiment.

FIG. 9 is a flowchart of a capacitance offset data updating process by the capacitance correction unit according to the embodiment.

FIG. 10 is a flowchart of a capacitance correction process by the capacitance correction unit according to the embodiment.

FIG. 11 illustrates an example of a functional configuration of a capacitance correction unit according to another embodiment.

FIG. 12 illustrates an example of sensitivity correction information stored in a sensitivity correction information storage unit according to the embodiment.

FIG. 13 is a flowchart of a capacitance offset data updating process by the capacitance correction unit according to the embodiment.

FIG. 14 is a flowchart of a capacitance correction process by the capacitance correction unit according to the embodiment.

### DESCRIPTION OF EMBODIMENTS

In an information processor having a capacitive sensor, the capacitive sensor is influenced by a usage state of the information processor. For example, when using such a mobile terminal that lies on a desk or the like, the capacitive sensor senses the capacitance between the mobile terminal and the hand operating the mobile terminal (hereinafter this capacitance is also referred to as a capacitance of an operating hand). However, when a user holds in a hand a mobile terminal that has a capacitive sensor, the capacitive sensor senses the capacitance of the operating hand of the user as well as the capacitance between the mobile terminal and the hand holding the mobile terminal (hereinafter this capacitance is also referred to as a capacitance of a holding hand). Moreover, when the user changes the way of holding the mobile terminal to change its usage state, the capacitance of the holding hand is also changed.

In this way, since an information processor having a capacitive sensor is influenced by the information processor usage state, accurate and reliable detection of the capacitance of the operating hand is difficult.

In an embodiment of an information processor having capacitance sensing means, capacitance can be accurately and reliably sensed according to an information processor usage state.

An information processor includes a contact sensing unit that senses contact; a capacitance sensing unit that senses capacitance; a capacitance offset information storage unit that stores offset capacitance information; a contact state change determining unit that obtains information indicating a contact state from the contact sensing unit and determines a change in the contact state sensed by the contact detecting unit; a capacitance correction control unit that obtains capacitance information from the capacitance sensing unit when the change in the contact state is determined by the contact state change determining unit, and updates offset capacitance information stored in the capacitance offset information storage unit with the obtained capacitance information; and a capacitance correction calculation unit that obtains the capacitance information from the capacitance sensing unit and uses the offset capacitance information stored in the capacitance offset information storage unit to correct the obtained capacitance information.

Capacitance information can be reliably and accurately obtained by responding to changes in the information processor usage state.

The following will be explained with reference to the drawings.

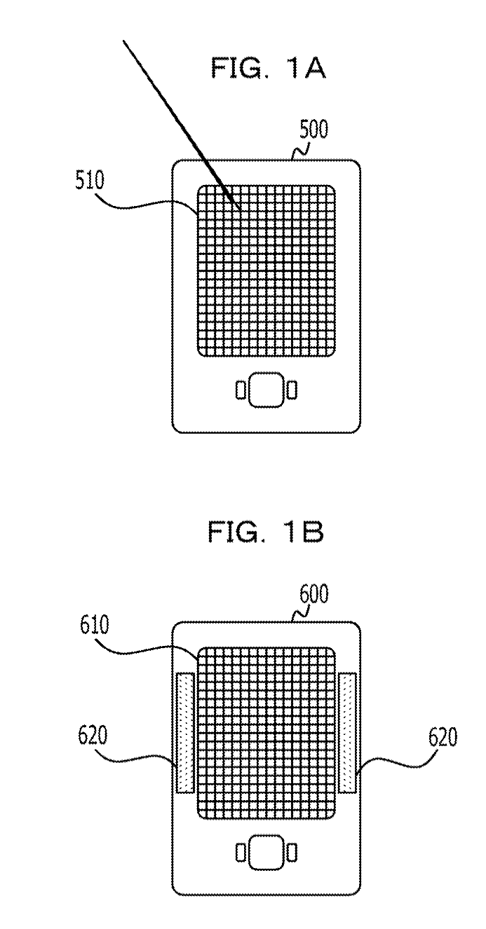

FIGS. 1A and 1B illustrate examples of an information processor that has capacitive sensors.

An information processor 500 illustrated in FIG. 1A is a portable device that includes a touch panel 510 that uses capacitive sensors. The capacitive sensors are disposed in a matrix in the touch panel 510 of the information processor 500. The capacitive sensors used in the touch panel 510 are a contact type of capacitive sensor. The contact type capacitive sensor detects operations by a user on the information processor 500 by sensing capacitance when the touch panel 510 is touched by a finger of the user. The contact type capacitive sensor detects touching by a finger on the touch panel 510 because of a rapid change in capacitance by touching the touch panel 510 with the finger of the user. In other words, it is difficult to detect changes in capacitance until a finger of the user touches the touch panel 510.

In information processor 600 illustrated in FIG. 1B is a portable device that includes a touch panel 610 that uses a capacitive sensor, and a high-sensitivity capacitive sensor 620 that has a higher sensitivity than the capacitive sensor of the touch panel 610. The capacitive sensors used in the touch panel 610 in the information processor 600 are a contact type of capacitive sensor similar to the capacitive sensor of the touch panel 510 on the information processor 500 illustrated in FIG. 1A. The capacitive sensor used by the touch panel 610 detects operations by a user on the information processor 600 by sensing capacitance when the touch panel 610 is touched by a finger of the user.

Conversely, the high-sensitivity capacitive sensor 620 is a non-contact type capacitive sensor that can sense capacitance when a user's finger comes close to the capacitive sensor without touching the touch panel 610. The high-sensitivity capacitive sensor 620 can also sense small capacitance formed between the sensor 620 and a finger of the user that is a short distance away.

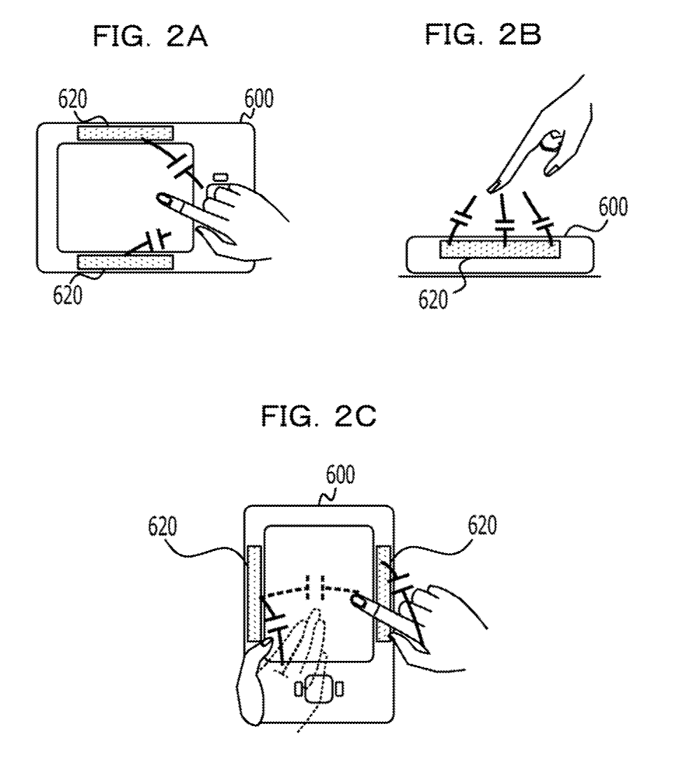

FIGS. 2A to 2C illustrate examples of usage states of an information processor that has high-sensitivity capacitive sensors.

The information processor 600 illustrated in FIGS. 2A to 2C includes the high-sensitivity capacitive sensor 620 illustrated in FIG. 1B. FIG. 2A is a top view of a usage state where a user uses the information processor 600 placed on a desk or the like. FIG. 2B is a side view of a usage state where a user uses the information processor 600 placed on a desk or the like. Furthermore, FIG. 2C is a top view of a usage state where a user uses the information processor 600 in his/her hands.

As illustrated in FIGS. 2A to 2C, the high-sensitivity capacitive sensor 620 in the information processor 600 senses the capacitance between the sensor 602 and a user's operating hand at a position that is a short distance away.

As illustrated in FIGS. 2A and 2B, the high-sensitivity capacitive sensor 620 senses the capacitance of the operating hand of the user when the user uses the information processor 600 placed on a desk and the like. However, when the user holds the information processor 600 in one hand while using the information processor 600 as illustrated in FIG. 2C, the high-sensitivity capacitive sensor 620 senses the capacitance of the holding hand as well as the capacitance of the operating hand of the user at the same time.

Capacitance C is represented in the following equation (1) where “d” is the distance between parallel conductors with the area “S” when a permittivity ε of a dielectric substance between the parallel conductors is evenly filled.

C=εS/d (1)

From equation (1), it can be understood that there is a larger influence on the high-sensitivity capacitive sensor 620 from a substance as the distance “d” becomes smaller. Therefore, when the user holds the information processor 600 in one hand while using the information processor 600 as illustrated in FIG. 2C, the high-sensitivity capacitive sensor 620 is influenced more by the capacitance of the holding hand of the user which is the hand closest to the high-sensitivity capacitive sensor 620.

In this way, the capacitance of the operating hand of the user influences the usage state of the information processor 600 when using the information processor 600 that includes the high-sensitivity capacitive sensor 620. That is, detection of the user operations on the information processor 600 is influenced by the usage state of the information processor 600.

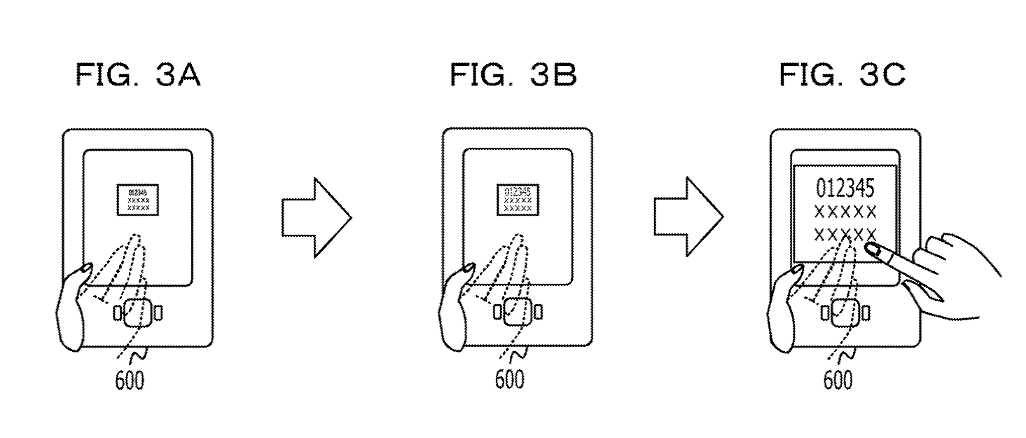

FIGS. 3A to 3C illustrate examples of usage states of an information processor held by a user.

The information processor 600 illustrated in FIGS. 3A to 3C includes the high-sensitivity capacitive sensor 620 illustrated in FIG. 1B and FIGS. 2A to 2C.

As described above, the capacitance sensed by the high-sensitivity capacitive sensor 620 is influenced by the usage state of the information processor 600. A possible method of controlling such influence of the usage, for example, is to store the capacitance value as an offset value, which is sensed when an application using the high-sensitivity capacitive sensor 620 is activated, and then use the offset value to correct a value determined by the high-sensitivity capacitive sensor 620.

For example, the user activates a software keyboard application that uses the high-sensitivity capacitive sensor 620 while holding the information processor 600 in one hand (FIG. 3A). The capacitance value sensed by the high-sensitivity capacitive sensor 620 in the information processor 600 when the application is activated is stored as the offset value (FIG. 3B). When the user moves a finger of the operating hand toward the information processor 600, the high-sensitivity capacitive sensor 620 senses the capacitance of the finger of the operating hand and enlarges the software keyboard displayed on the touch panel 610 according to a distance between the panel 610 and the finger (FIG. 3C). At this time, the capacitance value sensed by the high-sensitivity capacitive sensor 620 is corrected by the offset value held when the application was activated.

However, a state of usage of the information processor 600 often changes while the application is running when the way the information processor 600 is held changes or when the information processor 600 carried about is placed on a desk. When the usage changes in this way while the application is running, the method of adjusting the capacitance value, which was sensed by the high-sensitivity capacitive sensor 620, according to the offset value stored at the timing of starting of the application, cannot be applied.

The following describes an information processor according to the present embodiment in which sensed capacitance can be desirably corrected in response to changes in the usage state.

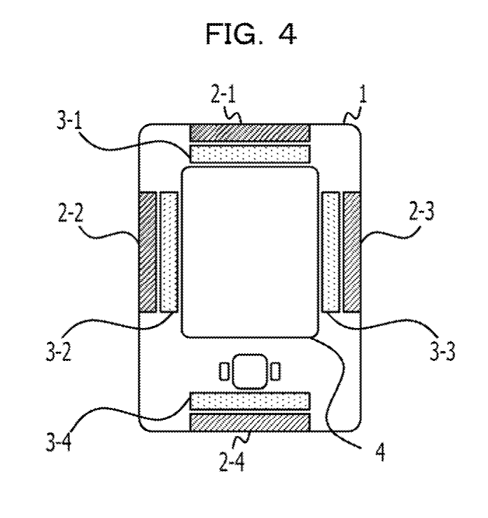

FIG. 4 illustrates an example of an information processor according to the present embodiment.

An information processor 1 illustrated in FIG. 4 is a portable terminal that a user can use while holding the portable terminal in a hand. The information processor 1 includes four contact sensing units 2 each placed on the top, left, right, and bottom sides, four capacitance sensing units 3 each placed on the top, left, right, and bottom sides, and a touch panel 4. The contact sensing units 2 and the capacitive sensing units 3 may be any number and may be placed in any location. It is desirable to have a plurality of the contact sensing units 2 and the capacitive sensing units 3.

The contact sensing units 2 sense contact with an object on the information processor 1. The contact sensing units 2 may include pressure sensors or infrared sensors. The contact sensing units 2 include a contact sensing unit 2-1, a contact sensing unit 2-2, a contact sensing unit 2-3, and a contact sensing unit 2-4 which are disposed on the top, left, right, and bottom respectively when looking at the front face of the touch panel 4 as illustrated in FIG. 4.

The capacitive sensing units 3 sense the capacitance between the information processor 1 and an object outside of the information processor 1 (hereinafter this capacitance is also referred to as a capacitance of an object). The capacitive sensing units 3 according to the present embodiment are enabled by highly sensitive capacitive sensors that can sense capacitance of an object that is close but not directly in contact. The capacitance sensing units 3 include a capacitance sensing unit 3-1, a capacitance sensing unit 3-2, a capacitance sensing unit 3-3, and a capacitance sensing unit 3-4 which are disposed on the top, left, right, and bottom respectively when looking at the front face of the touch panel 4 as illustrated in FIG. 4. The number of capacitive sensing units 3 may not be the same as the number of contact sensing units 2.

The touch panel 4 is an output device that displays a screen, and an input device that receives contact operations by a user. The input function of the touch panel 4 is achieved by conventional contact type capacitive sensors, resistance sensors, pressure sensors or the like.

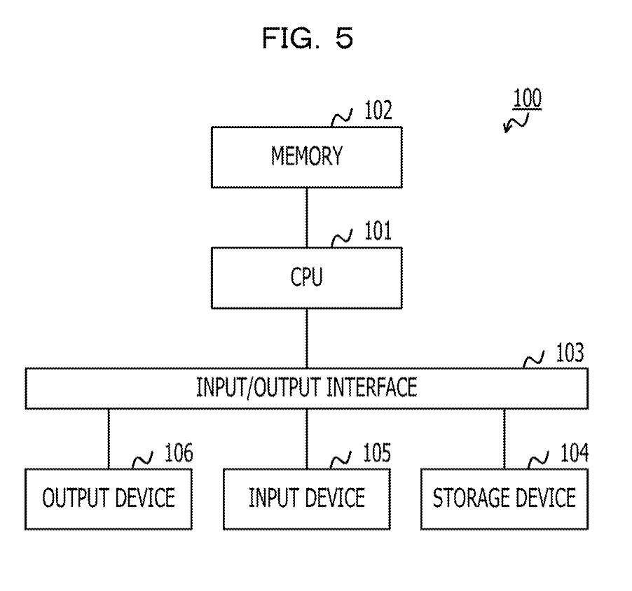

FIG. 5 illustrates an example of a hardware configuration of the information processor according to the present embodiment.

As illustrated in FIG. 5, the information processor 1 illustrated in FIG. 4 is realized by a computer 100 that includes a central processing unit (CPU) 101, a memory 102 that is a main memory, an input/output interface 103, a storage device 104, an input device 105, and an output device 106.

The input device 105 illustrated in FIG. 5 may be, for example, the touch panel 4 of the information processor 1 illustrated in FIG. 4. The touch panel 4 of the information processor 1 illustrated in FIG. 4 has a liquid crystal panel attached on the rear surface of the touch panel 4. The output device 106 illustrated in FIG. 5 is, for example, a liquid crystal panel. The input device 105 illustrated in FIG. 5 is, for example, the contact sensing units 2-1 to 2-4 of the information processor 1 illustrated in FIG. 4. The input device 105 illustrated in FIG. 5 is, for example, the capacitance sensing units 3-1 to 3-4 of the information processor 1 illustrated in FIG. 4.

A program to be executed by the computer 100 of the information processor 1 is stored in the storage unit 104, read from the memory 102 when executed, and executed by the CPU 101.

The computer 100 reads the program directly from a portable recording medium and conducts processing according to the program. Furthermore, the computer 100 may sequentially conduct processing according to received programs as each program is transferred from a server computer.

Furthermore, the program may be previously recorded in a recording medium that can be read by the computer 100.

First Embodiment

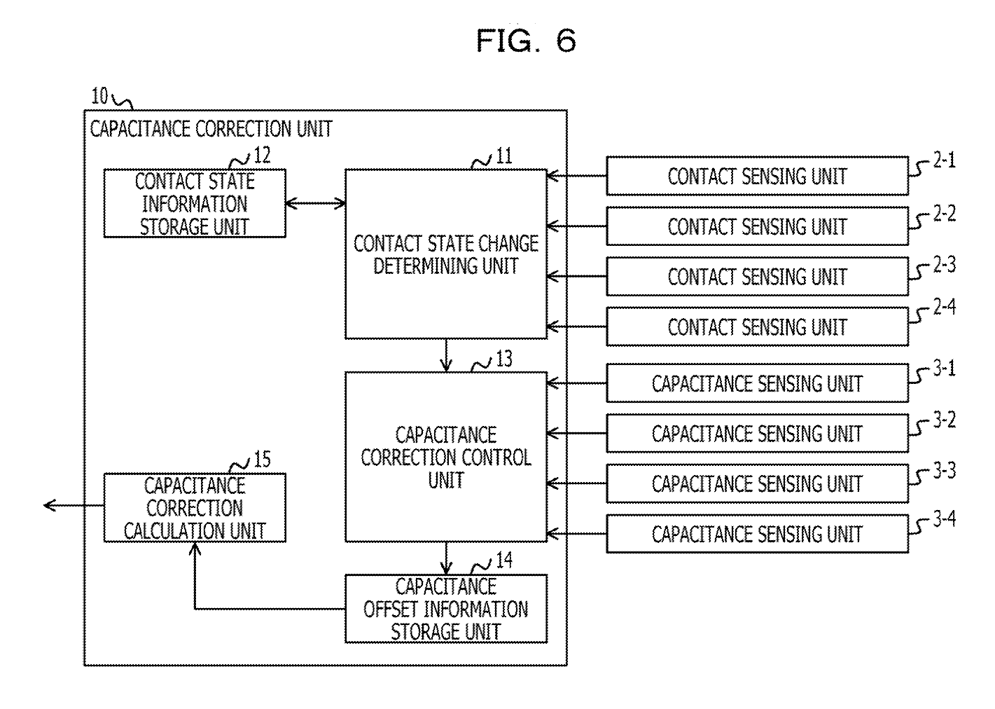

FIG. 6 illustrates an example of a functional configuration of a capacitance correction unit according to a first embodiment.

In the first embodiment, the information processor 1 illustrated in FIG. 4 includes a capacitance correction unit 10 illustrated in FIG. 6. The capacitance correction unit 10 corrects the capacitance sensed by the capacitance sensing units 3 according to the usage state of the information processor 1.

The capacitance correction unit 10 according to the first embodiment includes a contact state change determining unit 11, a contact state information storage unit 12, a capacitance correction control unit 13, a capacitance offset information storage unit 14, and a capacitance correction calculation unit 15. The capacitance correction unit 10 and the functional units included in the capacitance correction unit 10 are enabled by a software program and hardware such as the CPU 101 and the memory 102 included in the computer 100 of the information processor 1 illustrated in FIG. 5.

The contact state change determining unit 11 obtains contact information from the contact sensing units 2. The contact information indicates the contact state sensed by the contact sensing units 2. The contact state change determining unit 11 compares contact state information stored in the contact state information storage unit 12 and the contact information obtained from the contact sensing units 2, and determines whether there is any change in the contact state. The contact state information indicates the contact state sensed by the contact sensing units 2 at a certain time.

The contact state information storage unit 12 is a computer-accessible storage unit that stores the contact state information. For example, first the contact state information storage unit 12 stores the contact state information which is the recorded contact state sensed by the contact sensing units 2 when the information processor 1 power is turned on. Next, the contact state information stored in the contact state information storage unit 12 is updated with the changed contact state when the contact state change determining unit 11 determines that the contact state of the information processor 1 has changed.

The contact state change determining unit 11 sends the contact state change information that indicates that the contact state of the information processor 1 has changed to the capacitance correction control unit 13 when a change in the contact state has been determined. Furthermore, the contact state change determining unit 11 updates the contact state information stored in the contact state information storage unit 12 with the contact information obtained from the contact sensing units 2 when a change in the contact state has been determined.

The capacitance correction control unit 13 obtains capacitance information from the capacitive sensing units 3. The capacitance information is measurement information of capacitance sensed by the capacitance sensing units 3. The capacitance correction control unit 13 passes the capacitance information obtained from the capacitance sensing units 3 to the capacitance correction calculation unit 15. Furthermore, the capacitance correction control unit 13 updates capacitance offset information stored in the capacitance offset information storage unit 14 with the capacitance information obtained from the capacitance sensing units 3 when the contact state change information is received from the contact state change determining unit 11. The capacitance offset information holds the capacitance values sensed by the capacitance sensing units 3 when a change in the contact state of the information processor 1 is confirmed, as offset capacitance values.

The capacitance offset information storage unit 14 is a computer accessible storage unit that stores the capacitance offset information. For example, the capacitance offset information storage unit 14 first stores the capacitance offset information that holds the capacitance values sensed by the capacitance sensing units 3 when the information processor 1 power is turned on, as the offset capacitance value. Then, the capacitance offset information stored in the contact state information storage unit 14 is updated with the capacitance information obtained from the capacitance sensing units 3 when a change in the contact state of the information processor 1 is determined by the contact state change determining unit 11.

The capacitance correction calculation unit 15 uses the capacitance offset information stored in the capacitance offset information storage unit 14 to update the capacitance information obtained by the capacitance sensing units 3 via the capacitance correction control unit 13. The capacitance correction calculation unit 15 outputs the corrected capacitance information.

For example, the capacitance value sensed by a capacitance sensing unit 3-i is Cᵢ org, and an offset capacitance value corresponding to the capacitance sensing unit 3-i held in the capacitance offset information is Cᵢ offset. The capacitance correction calculation unit 15 uses the following equation (2) to conduct a calculation to correct the capacitance sensed by the capacitance sensing unit 3-i.

Cᵢ cal=Cᵢ org−Cᵢ offset (2)

In equation (2), the corrected capacitance value Cᵢ cal is derived by removing the influence of the usage state of the information processor 1 from the capacitance value sensed by the capacitance sensing unit 3-i.

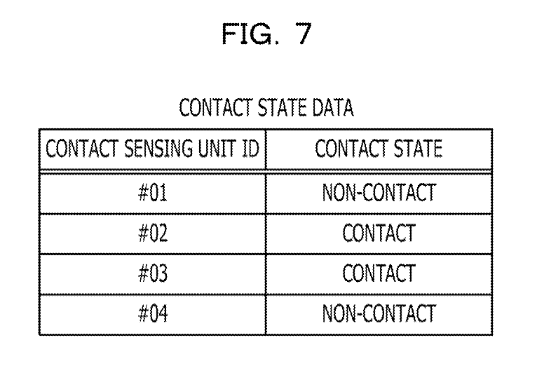

FIG. 7 illustrates an example of contact state information stored in a contact state information storage unit according to the present embodiment.

Contact state data illustrated in FIG. 7 is an example of the contact state information stored in the contact state information storage unit 12. The contact state data illustrated in FIG. 7 includes contact state information and contact sensing unit ID information.

The contact sensing unit ID of the contact state data illustrated in FIG. 7 is identification information that uniquely identifies the contact sensing units 2 included in the information processor 1. In the contact state data illustrated in FIG. 7, “#01” represents the contact sensing unit ID of the contact sensing unit 2-1, “#02” represents the contact sensing unit ID of the contact sensing unit 2-2, “#03” represents the contact sensing unit ID of the contact sensing unit 2-3, and “#04” represents the contact sensing unit ID of the contact sensing unit 2-4.

The contact state in the contact state data illustrated in FIG. 7 indicates the contact states sensed by the contact sensing units 2 at a certain time. As illustrated in FIG. 7, the contact state is represented by two values of “sensed” and “not sensed” in the present embodiment. “Sensed” indicates that contact from some object has been sensed by the applicable contact sensing unit 2. “Not sensed” indicates that no contact has been sensed by the applicable contact sensing unit 2.

The contact states recorded in the contact state data may be represented by one or more values. For example, when the contact sensing units 2 are enabled by pressure sensors, the contact state recorded in the contact state data may be pressure values sensed by the pressure sensors of the contact sensing units 2. In this case, the contact state change determining unit 11 compares the pressure values derived from the contact information obtained from the contact sensing units 2 with pressure values recorded in the contact state data, and determines that a change in the contact state of the information processor 1 has occurred when the pressure value is equal to or greater than a certain threshold.

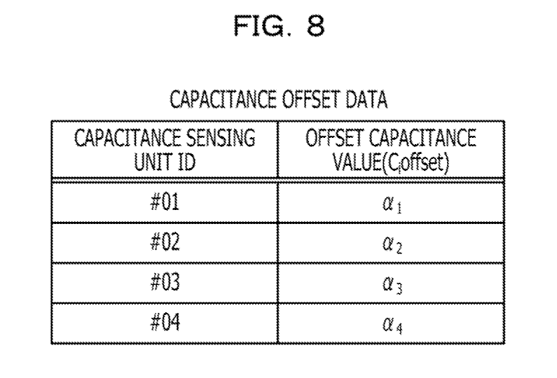

FIG. 8 illustrates an example of capacitance offset information stored in a capacitance offset information storage unit according to the present embodiment.

The capacitance offset data illustrated in FIG. 8 is an example of the capacitance offset information stored in the capacitance offset information storage unit 14. The capacitance offset data illustrated in FIG. 8 includes a capacitance sensing unit ID information and offset capacitance value information.

The capacitive sensing unit ID of the capacitance offset data illustrated in FIG. 8 is identification information for uniquely identifying the capacitance sensing units 3 in the information processor 1. In the capacitance offset data illustrated in FIG. 8, “#01” represents the capacitance sensing unit ID for the capacitance sensing unit 3-1, “#02” represents the capacitance sensing unit ID for the capacitance sensing unit 3-2, “#03” represents the capacitance sensing unit ID for the capacitance sensing unit 3-3, and “#04” represents the capacitance sensing unit ID for the capacitance sensing unit 3-4.

The offset capacitance values in the capacitance offset data illustrated in FIG. 8 are offset capacitance values Cᵢoffset (i=1, 2, 3, 4) for correcting the capacitance values Cᵢorg (i=1, 2, 3, 4) sensed by the capacitance sensing units 3 in the capacitance correction calculation unit 15. In the capacitance offset data illustrated in FIG. 8, the values α1, α2, α3, and α4 are capacitance values sensed by the capacitance sensing unit 3-1, the capacitance sensing unit 3-2, the capacitance sensing unit 3-3, and the capacitance sensing unit 3-4 respectively when the usage state of the information processor 1 changes.

For example, assume that the contact state information at a certain time stored in the contact state information storage unit 12 is the contact state data illustrated in FIG. 7. Furthermore, assume that the capacitance offset information at the same time stored in the capacitance offset information storage unit 14 is the capacitance offset data illustrated in FIG. 8.

First, the contact state change determining unit 11 obtains the contact information “not sensed,” “sensed,” “sensed,” and “not sensed,” which represents the results of contact states sensed respectively by the capacitance sensing unit 2-1, capacitance sensing unit 2-2, capacitance sensing unit 2-3, and capacitance sensing unit 2-4. At this time, the contact state change determining unit 11 determines that there is no change in the contact state of the information processor 1 by comparing the contact states obtained from the capacitance sensing units 2 and the contact state data recorded in the contact state information storage unit 12 as illustrated in FIG. 7. In this case, the capacitance offset data stored in the capacitance offset information storage unit 14 as illustrated in FIG. 8 is not updated.

Next, the contact state change determining unit 11 obtains contact information “not sensed,” “sensed,” “not sensed,” and “sensed,” which represents the results of contact states sensed respectively by the capacitance sensing unit 2-1, capacitance sensing unit 2-2, capacitance sensing unit 2-3, and capacitance sensing unit 2-4. At this time, the contact state change determining unit 11 determines that there is a change in the contact state of the information processor 1 by comparing the contact states from the capacitance sensing units 2 and the contact state data stored in the contact state information storage unit 12 as illustrated in FIG. 7.

At this time, the contact state change determining unit 11 sends contact state change information to the capacitance correction control unit 13. Furthermore, the contact state change determining unit 11 updates the contact state data stored in the contact state information storage unit 12 as illustrated in FIG. 7 by using the contact information obtained from the capacitance sensing units 2. The contact state information of the contact state data stored in the contact state information storage unit 12 as illustrated in FIG. 7 is rewritten as “not sensed,” “sensed,” “not sensed,” and “sensed” in order from top to bottom.

The capacitance correction control unit 13 that receives the contact state change information from the contact state change determining unit 11 updates the capacitance offset data stored in the capacitance offset information storage unit 14 as illustrated in FIG. 8 with the capacitance information obtained from the capacitance sensing units 3. Here, the capacitance information β1, β2, β3, and β4 is obtained as capacitance sensing results from the capacitance sensing unit 3-1, capacitance sensing unit 3-2, capacitance sensing unit 3-3, and capacitance sensing unit 3-4 respectively. The offset capacitance value information in the capacitance offset data stored in the capacitance offset information storage unit 14 as illustrated in FIG. 8 is rewritten as β1, β2, β3, and β4 in order from top to bottom.

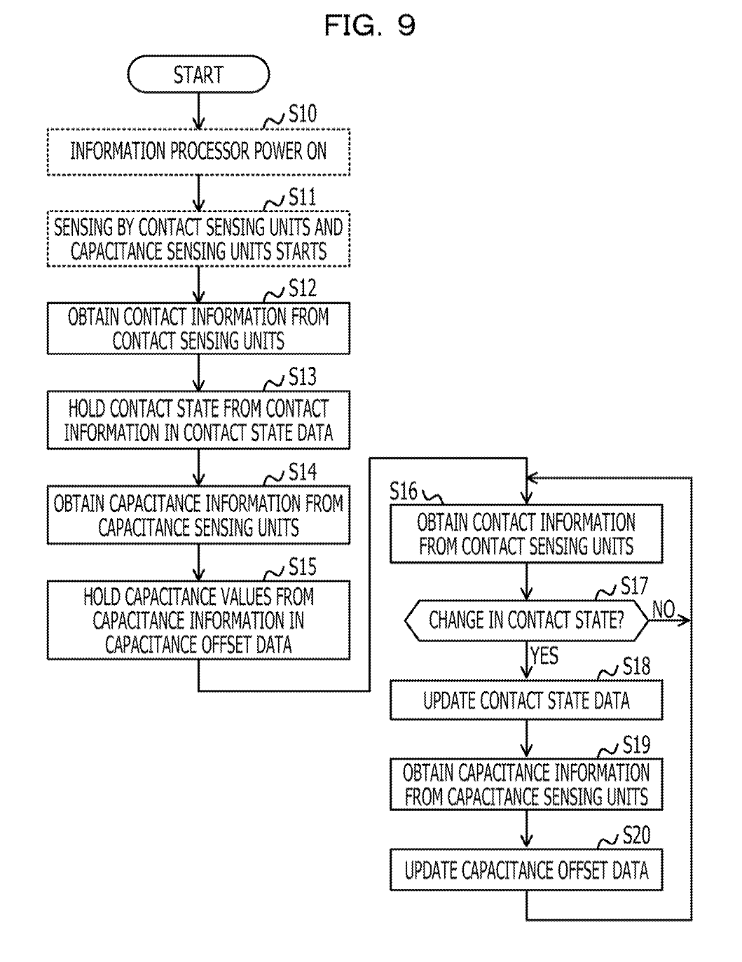

FIG. 9 is a flowchart of a capacitance offset data updating process by the capacitance correction unit according to the first embodiment.

The information processor 1 power is turned on (step S10) and sensing by the contact sensing units 2 and the capacitance sensing units 3 is started (step S11).

While the power of the information processor 1 is on, the contact state change determining unit 11 of the capacitance correction unit 10 obtains contact information from the contact sensing units 2 (step S12). The contact state change determining unit 11 holds the contact state derived from the obtained contact information in the contact state data stored in the contact state information storage unit 12 (step S13). The contact state data held at this time is initial contact state data.

Furthermore, while the power of the information processor 1 is on, the capacitance correction control unit 13 of the capacitance correction unit 10 obtains the capacitance information from the capacitance sensing units 3 (step S14). The capacitance correction control unit 13 holds the capacitance values derived from the obtained capacitance information as offset capacitance values in the capacitance offset data stored in the capacitance offset information storage unit 14 (step S15). The capacitance offset data held at this time is initial capacitance offset data.

While the information processor 1 is running, the capacitance correction unit 10 repeats the following steps S16 to S20.

The contact state change determining unit 11 obtains the contact information from the contact sensing units 2 (step S16). The contact state change determining unit 11 determines if there has been any change in the contact state of the information processor 1 by comparing the obtained contact information and the contact state data stored in the contact state information storage unit 12 (step S17).

If the contact state has not changed (step S17: No), the process returns to step S16 and the contact state change determining unit 11 returns to the step of obtaining contact information from the contact sensing units 2.

If the contact state has not changed (step S17: Yes), the contact state change determining unit 11 updates the contact state data stored in the contact state information storage unit 12 using the contact information obtained from the contact sensing units 2 (step S18). Furthermore, the capacitance correction control unit 13 obtains the capacitance information from the capacitive sensing units 3 (step S19). The capacitance correction control unit 13 updates the capacitance offset data stored in the capacitance offset information storage unit 14 using the capacitance information obtained from the capacitance sensing units 3 (step S20). Returning to step S16, the contact state change determining unit 11 moves to the step of obtaining contact information from the contact sensing units 2.

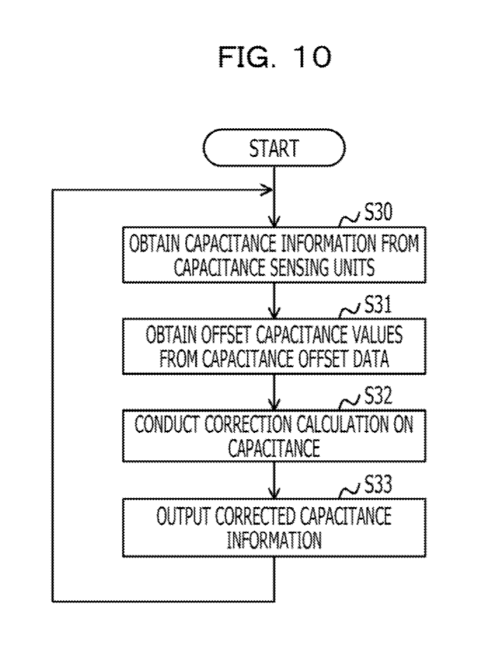

FIG. 10 is a flowchart of a capacitance correction process by the capacitance correction unit according to the first embodiment.

The capacitance updating process illustrated in FIG. 10 is conducted concurrently with the capacitance offset data updating process illustrated in FIG. 9. While the information processor 1 is running, the capacitance correction unit 10 repeats the following steps S30 to S33.

When the capacitance sensing by the capacitance sensing units 3 starts, the capacitance correction calculation unit 15 obtains the capacitance information from the capacitance sensing units 3 through the capacitance correction control unit 13 (step S30). Furthermore, the capacitance correction calculation unit 15 obtains the offset capacitance values from the capacitance offset data stored in the capacitance offset information storage unit 14 (step S31).

The capacitance correction calculation unit 15 uses the obtained offset capacitance values to conduct correction calculations on the capacitance sensed by the capacitance sensing units 3 (step S32). In this case, for example, the capacitance correction calculation unit 15 uses the abovementioned equation (2) to conduct the correction calculations. The capacitance correction calculation unit 15 outputs the corrected capacitance information (step S33).

Returning to step S30, the capacitance correction calculation unit 15 moves to the step of obtaining the capacitance information from the capacitance sensing units 3.

The capacitance correction unit 10 of the first embodiment updates the offset capacitance data for correcting the capacitance sensed by the capacitance sensing units 3 in response to changes in the contact state of the information processor 1. As a result, capacitance can be accurately and reliably sensed even under conditions where there is change in the usage state of the information processor 1.

Second Embodiment

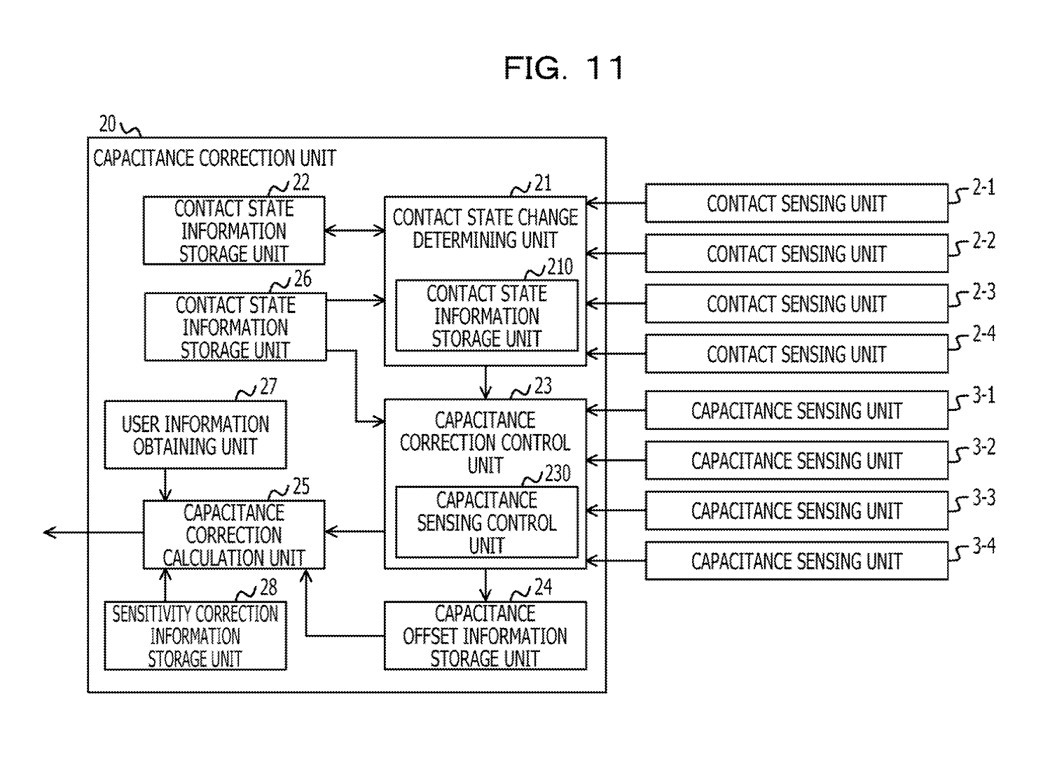

FIG. 11 illustrates an example of a functional configuration of a capacitance correction unit according to a second embodiment.

In the second embodiment, the information processor 1 illustrated in FIG. 4 includes a capacitance correction unit 20 illustrated in FIG. 11. The capacitance correction unit 20 corrects the capacitance sensed by the capacitance sensing units 3 in response to the usage state of the information processor 1.

In the capacitance correction unit 20 according to the second embodiment, the portions that update the offset capacitance data when the contact states sensed by the contact sensing units 2 have changed are similar to the abovementioned first embodiment. The capacitance correction unit 20 according to the second embodiment further corrects the capacitance sensed by the capacitance sensing units 3 only when particular applications using the capacitance sensing units 3 are conducted. Furthermore, the capacitance correction unit 20 of the second embodiment also corrects sensitivity of the capacitance sensed by the capacitance sensing units 3 for each user using the information processor 1.

The capacitance correction unit 20 of the second embodiment includes a contact state change determining unit 21, a contact state information storage unit 22, a capacitance correction control unit 23, a capacitance offset information storage unit 24, a capacitance correction calculation unit 25, an application operation determining unit 26, a user information obtaining unit 27, and a sensitivity correction information storage unit 28. The capacitance correction unit 20 and the functional units included in the capacitance correction unit 20 are enabled by a software program and hardware such as the CPU 101 and the memory 102 included in the computer 100 of the information processor 1 illustrated in FIG. 5.

The contact state information storage unit 22 and the capacitance offset information storage unit 24 of the capacitance correction unit 20 are similar to the contact state information storage unit 12 and the capacitance offset information storage unit 14 of the abovementioned capacitance correction unit 10 of the first embodiment, and the description will be omitted. The contact state change determining unit 21 and the capacitance correction control unit 23 of the capacitance correction unit 20 are in principle similar to the contact state change determining unit 11 and the capacitance correction control unit 13 of the abovementioned capacitance correction unit 10 of the first embodiment. Only the parts of the contact state change determining unit 21 and the capacitance correction control unit 23 that are different from the abovementioned first embodiment will be described below.

The application operation determining unit 26 determines the particular application operation that uses the capacitance sensing units 3. The application operation determining unit 26 notifies the contact state change determining unit 21 and the capacitance correction control unit 23 that activation of the particular application that uses the capacitance sensing units 3 has been determined. Further, the application operation determining unit 26 notifies the contact state change determining unit 21 and the capacitance correction control unit 23 that termination of the particular application that uses the capacitance sensing units 3 has been determined.

The contact state change determining unit 21 of the second embodiment includes a contact sensing control unit 210. The contact sensing control unit 210 sends a control signal to each of the contact sensing units 2 to start contact state sensing when the particular application that uses the capacitance sensing units 3 is activated. The contact sensing control unit 210 sends a control signal to each of the contact sensing units 2 to terminate contact state sensing when the particular application that uses the capacitance sensing units 3 is terminated.

The capacitance correction control unit 23 of the second embodiment includes a capacitance sensing control unit 230. The capacitance sensing control unit 230 sends a control signal to each of the capacitance sensing units 3 to start capacitance sensing when the particular application that uses the capacitance sensing units 3 is activated. Further, the capacitance sensing control unit 230 sends a control signal to each of the capacitance sensing units 3 to terminate capacitance sensing when the particular application that uses the capacitance sensing units 3 is terminated.

In this way, the capacitance correction unit 20 of the second embodiment controls turning the contact sensing units 2 and the capacitance sensing units 3 on and off by the application operation determining unit 26, the contact sensing control unit 210, and the capacitance sensing control unit 230 in response to the operation of the application. As a result, the information processor 1 can save energy since the contact sensing units 2 and the capacitance sensing units 3 are operated only when the application that uses the capacitance sensing units 3 is running.

The user information obtaining unit 27 obtains information that identifies the user using the information processor 1. In the second embodiment, for example, the user using the information processor 1 is identified by conducting user verification when, for example, the information processor 1 is activated or when the particular application that uses the capacitance sensing units 3 is activated. The user information obtaining unit 27 sends the obtained user information to the capacitance correction calculation unit 25.

The sensitivity correction information storage unit 28 is a computer-readable storage unit that stores sensitivity correction information. The sensitivity correction information is stored information on sensitivity correction values set for each user using the information processor 1.

Since the permittivity of each user is different, the capacitance sensitivity sensed by the capacitance sensing units 3 is different for each user even when using the same information processor 1. In the second embodiment, the sensitivity of the capacitance sensing of each user is corrected since an appropriate user specific capacitance can be obtained. For example, a sensitivity correction value obtained by conducting multiple calibrations using the information processor 1 while the sensitivity correction value of each user changes to derive the optimum capacitance sensing sensitivity may be employed as the user specific sensitivity correction value recorded in the sensitivity correction information.

The capacitance correction calculation unit 25 corrects the capacitance information obtained by the capacitance sensing units 3 through the capacitance correction control unit 23 using the capacitance offset information stored in the capacitance offset information storage unit 24 and sensitivity correction information stored in the sensitivity correction information storage unit 28. The capacitance correction calculation unit 25 outputs the corrected capacitance information. The capacitance correction calculation unit 25 obtains the sensitivity correction value of the user by referring to the sensitivity correction information stored in the sensitivity correction information storage unit 28 with user information received from the user information obtaining unit 27.

For example, the capacitance value sensed by a capacitance sensing unit 3-i is Cᵢorg, and an offset capacitance value corresponding to the capacitance sensing unit 3-i held in the capacitance offset information is Cᵢoffset. Furthermore, the sensitivity correction value recorded in the sensitivity correction information of a user “x” is “D_{X}.” Here, the capacitance correction calculation unit 25 uses the following equation (3) to conduct a calculation to correct the capacitance sensed by the capacitance sensing unit 3-i.

Cᵢcal=Dₓ·(Cᵢorg−Cᵢoffset) (3)

In equation (3), the corrected capacitance value Cᵢcal is derived by removing the influence of the usage state of the information processor 1 from the capacitance value sensed by the capacitance sensing unit 3-i.

In this way, by using the user information obtaining unit 27, the sensitivity correction information storage unit 28, and the capacitance correction calculation unit 25, the capacitance correction unit 20 of the second embodiment can correct differences in the sensitivity of the capacitance sensing conducted by the capacitance sensing units 3 for each user. As a result, capacitance can be accurately and reliably sensed in for each user even when more than one user uses the information processor 1.

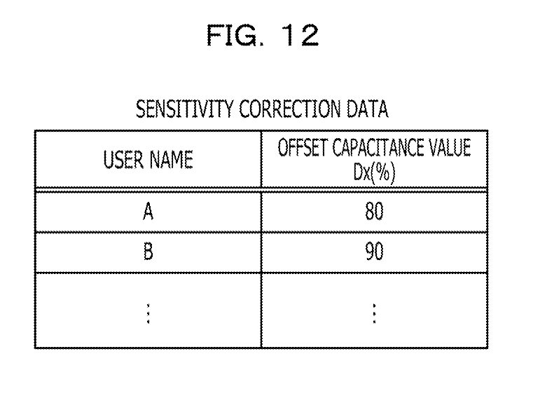

FIG. 12 illustrates an example of sensitivity correction information stored in a sensitivity correction information storage unit according to the present embodiment.

The sensitivity correction data illustrated ion FIG. 12 is an example of the sensitivity correction information recorded in the sensitivity correction information storage unit 28. The sensitivity correction data illustrated in FIG. 12 includes a user name and a sensitivity correction value.

The user name of the sensitivity correction data illustrated in FIG. 12 is a previously recorded name of a user who uses the information processor 1. The sensitivity correction value of the sensitivity correction data illustrated in FIG. 12 is the correction value D_{X} for correcting differences in the sensitivity of the capacitance sensed by the capacitance sensing units 3 for each user.

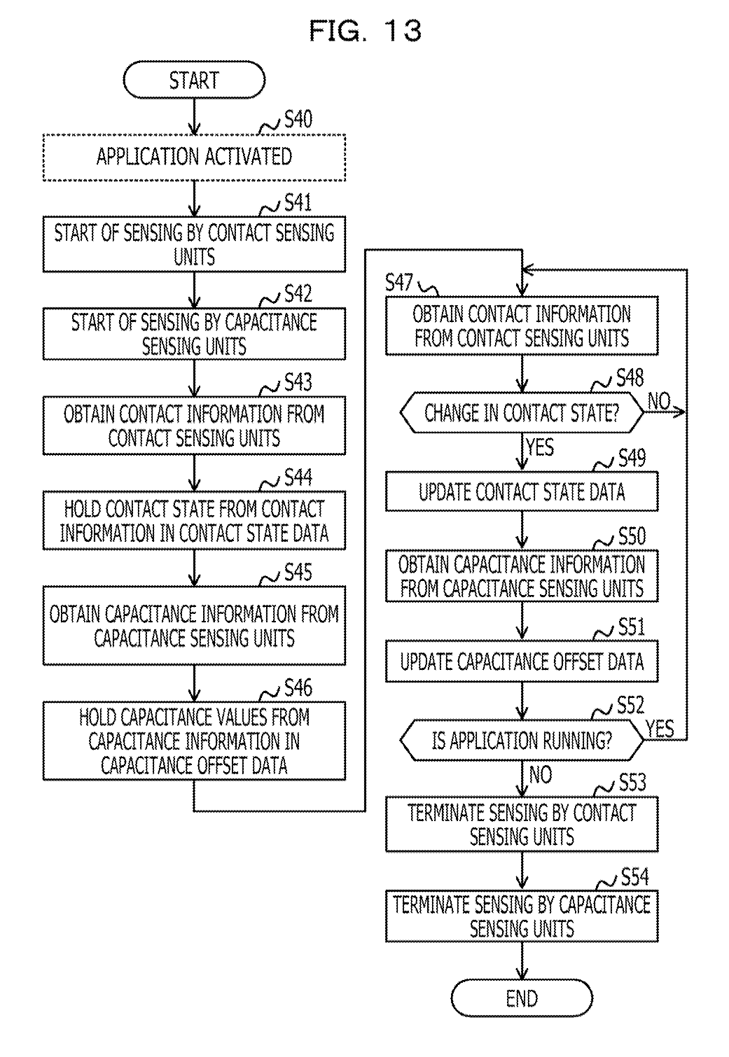

FIG. 13 is a flowchart of a capacitance offset data updating process by the capacitance correction unit according to the second embodiment.

A particular application that uses the capacitance sensing units 3 is activated in the information processor 1 (step S40). The application operation determining unit 26 of the capacitance correction unit 20 senses the activation of the application at this time. The contact sensing control unit 210 controls the start of the contact state sensing by the contact sensing units 2 (step S41). The capacitance sensing control unit 230 controls the start of the capacitance sensing by the capacitance sensing units 3 (step S42).

The contact state change determining unit 21 of the capacitance correction unit 20 obtains contact information from the contact sensing units 2 when the particular application that uses the capacitance sensing units 3 is activated (step S43). The contact state change determining unit 21 holds the contact state derived from the obtained contact information in the contact state data stored in the contact state information storage unit 22 (step S44). The contact state data held at this time is initial contact state data.

Furthermore, the capacitance correction control unit 23 of the capacitance correction unit 20 obtains the capacitance information from the capacitance sensing units 3 when the particular application that uses the capacitance sensing units 3 is activated (step S45). The capacitance correction control unit 23 holds the capacitance values derived from the obtained capacitance information as offset capacitance values in the capacitance offset data stored in the capacitance offset information storage unit 24 (step S46). The capacitance offset data held at this time is initial capacitance offset data.

The capacitance correction unit 20 repeats the following steps S47 to S52 while the particular application that uses the capacitance sensing units 3 is running.

The contact state change determining unit 21 obtains contact information from the contact sensing units 2 (step S47). The contact state change determining unit 21 determines if there has been any change in the contact state of the information processor 1 by comparing the obtained contact information and the contact state data stored in the contact state information storage unit 22 (step S48).

If the contact state has not changed (step S48: No), the process returns to step S47 and the contact state change determining unit 21 moves to the step of obtaining the next contact information from the contact sensing units 2.

If the contact state has changed (step S48: Yes), the contact state change determining unit 21 updates the contact state data stored in the contact state information storage unit 22 using the contact information obtained from the contact sensing units 2 (step S49). Furthermore, the capacitance correction control unit 23 obtains the capacitance information from the capacitive sensing units 3 (step S50). The capacitance correction control unit 23 updates the capacitance offset data stored in the capacitance offset information storage unit 24 using the capacitance information obtained from the capacitance sensing units 3 (step S51). The application operation determining unit 26 determines whether the particular application that uses the capacitance sensing units 3 is still running or not (step S52).

If the application is running (step S52: Yes), the process returns to step S47 and the contact state change determining unit 21 moves to the step of obtaining the next contact information from the contact sensing units 2.

If the application is not running (step S52: No), that is if the application has been terminated, the contact sensing control unit 210 controls the termination of the contact state sensing by the contact sensing units 2 (step S53). The capacitance sensing control unit 230 controls the termination of the capacitance sensing by the capacitance sensing units 3 (step S54).

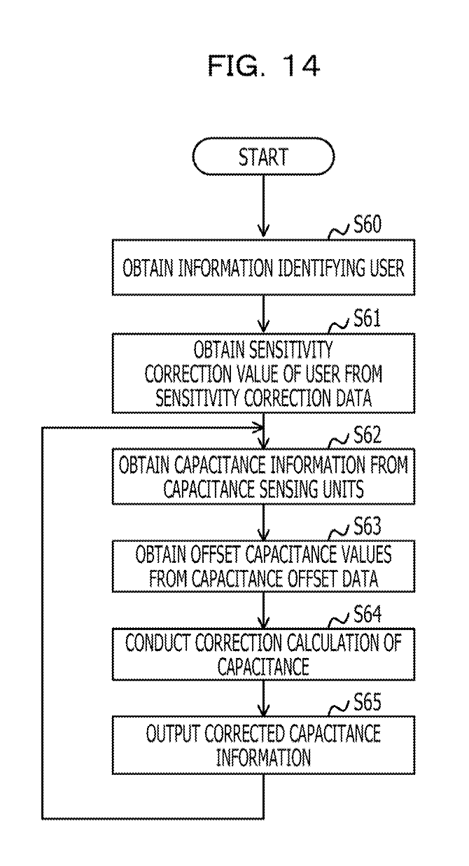

FIG. 14 is a flowchart of a capacitance correction process by the capacitance correction unit according to the second embodiment.

The capacitance correcting process illustrated in FIG. 14 is conducted concurrently with the capacitance offset data updating process illustrated in FIG. 13.

When the particular application that uses the capacitance sensing units 3 is activated in the information processor 1, the user information obtaining unit 27 obtains information identifying the user using the information processor 1 (step S60). The capacitance correction calculation unit 25 obtains the sensitivity correction value of the user using the information processor 1 from the sensitivity correction data stored in the sensitivity correction information storage unit 28 (step S61).

The capacitance correction calculation unit 25 of the capacitance correction unit 20 repeats the following steps S62 to S65 while the particular application that uses the capacitance sensing units 3 is running.

When the capacitance sensing by the capacitance sensing units 3 starts, the capacitance correction calculation unit 25 obtains the capacitance information from the capacitance sensing units 3 through the capacitance correction control unit 23 (step S62). Furthermore, the capacitance correction calculation unit 25 obtains the offset capacitance values from the capacitance offset data stored in the capacitance offset information storage unit 24 (step S63).

The capacitance correction calculation unit 25 uses the obtained sensitivity correction values and the obtained offset capacitance values to conduct correction calculations on the capacitance sensed by the capacitance sensing units 3 (step S64). In this case, for example, the capacitance correction calculation unit 25 uses the abovementioned equation (3) to conduct the correction calculations. The capacitance correction calculation unit 25 outputs the corrected capacitance information (step S65).

Returning to step S62, the capacitance correction calculation unit 25 moves to the process of obtaining the next capacitance information from the capacitance sensing units 3.

Although the present invention has been described using the above embodiments, various modifications can be made without departing from the spirit of the invention.

For example, the present embodiments describe examples of correcting capacitance sensed by non-contact highly sensitive capacitive sensors. However, correcting capacitance sensed by contact type capacitive sensors may also be used in the present embodiments.

Furthermore, the present embodiments describe a portable terminal type of information processor. However, a desk-top type of information processor may also be used in the present embodiments. The possibility exists that the contact state of a user of the information processor may change when the user holds the device with one hand and uses the other hand to conduct operations even with desk-top type information processors.

The program described in the present embodiments may be recorded on a computer-readable storage medium and distributed. Examples of computer-readable storage media include non-volatile storage media such as a floppy disc, a hard disc, a CD-ROM (compact disc—read only memory), a DVD-ROM, a DVD-RAM (DVD-random access memory), a BD (Blue-ray disc), a USB memory, and a flash memory.

A computer program may also be transmitted via a network such as the Internet, a wireless or wired communication line, or a telecommunication line. However, the computer-readable storage media does not include a carrier wave with an embedded computer program. But whether or not a computer program is embedded in a carrier wave and transmitted, a computer-readable storage medium installed in the computer sending the program exists. As a result, a computer-readable storage medium is a physical storage medium.

The program described in the embodiments is executed by the information processor as described with the example of the disc driver function installed in the information processor. However, the execution of the program is not limited in this respect. The program described in the embodiments may be executed by a processor installed in an input device. In this case, the program described in the embodiments may be recorded in a flash memory installed in the input device as firmware.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention(s) has(have) been described in detail, it should be understood that the various changes, substitutions, and alterations could be made hereto without departing from the spirit and scope of the invention.

What is claimed is:

1. An information processor comprising:
a contact sensing unit that senses contact;
a capacitance sensing unit that senses capacitance;
a capacitance offset information storage unit that stores offset capacitance information;
a contact state change determining unit that obtains information indicating a contact state from the contact sensing unit and determines a change in the contact state sensed by the contact sensing unit;
a capacitance correction control unit that obtains capacitance information from the capacitance sensing unit when the change in the contact state is determined by the contact state change determining unit, and updates offset capacitance information stored in the capacitance offset information storage unit with the obtained capacitance information; and
a capacitance correction calculation unit that obtains the capacitance information from the capacitance sensing unit and uses the offset capacitance information stored in the capacitance offset information storage unit to correct the obtained capacitance information.

2. The information processor according to claim 1, further comprising:
an application operation determining unit that determines whether a particular application is running,
a contact sensing control unit that terminates sensing by the contact sensing unit when the running of the particular application is terminated, and
a capacitance sensing control unit that terminates sensing by the capacitance sensing unit when the running of the particular application is terminated.

3. The information processor according to claim 1, further comprising:
a sensitivity correction information storage unit that stores sensitivity correction information set for each user; and
a user information obtaining unit that obtains information that identifies a user using the information processor; wherein
the capacitance correction calculation unit obtains the sensitivity correction information of the user using the information processor from the sensitivity correction information storage unit, and uses the offset capacitance information stored in the capacitance offset information storage unit and the obtained sensitivity correction information to correct the capacitance information obtained from the capacitance sensing unit.

4. An information processor comprising:
a contact sensing unit that senses contact,
a capacitance sensing unit that senses capacitance,
a memory that stores offset capacitance information, and
a processor that conducts processing, wherein
the processor conducts updating processing that includes:
obtaining information that indicates a contact state from the contact sensing unit,
determining a change in the contact state sensed by the contact sensing unit,
obtaining capacitance information from the capacitance sensing unit when the change in the contact state is determined, and
updating, with the obtained capacitance information, the offset capacitance information stored in the memory; and
the processor conducts correcting processing that includes:
obtaining information that indicates a contact state from the contact sensing unit,
reading the offset capacitance information stored in the memory based on the obtained contact state,
obtaining capacitance information from the capacitance sensing unit, and
using the read offset capacitance information to correct the obtained capacitance information.

5. A recording medium recording a program executable by a computer,
the program causing the computer to conduct an updating process that includes:
obtaining information that indicates a contact state from a contact sensing unit that senses contact, the sensing unit included in the computer,
determining a change in the contact state sensed by a capacitance sensing unit that senses capacitance, the capacitance sensing unit included in the computer,
obtaining capacitance information from the capacitance sensing unit when the change in the contact state is determined, and
updating, with the obtained capacitance information, offset capacitance information stored in a memory that stores the offset capacitance information; and
the program causing the computer to conduct a correcting process that includes:
obtaining information that indicates a contact state from the contact sensing unit,
reading the offset capacitance information stored in the memory based on the obtained contact state,
obtaining capacitance information from the capacitance sensing unit, and
using the read offset capacitance information to correct the obtained capacitance information.
